(19) United States
(12) Patent Application Publication
(10) Pub. No.: US 2026/0305204 A1
(43) Pub. Date: Oct. 1, 2026

(54) LASER ABLATION OF BACKSIDE DIELECTRIC TO ADJUST SUBSTRATE WARPAGE

(71) Applicant: Applied Materials, Inc., Santa Clara, CA (US)

(72) Inventors: MICHAEL RICE, Pleasanton, CA (US); WEI-SHENG LEI, San Jose, CA (US); PRADEEP SUBRAHMANYAN, Los Gatos, CA (US); YI ZHENG, Sunnyvale, CA (US); OLGA KUCHER, San Jose, CA (US)

(21) Appl. No.: 19/094,655

(22) Filed: Mar. 28, 2025

(51) Int. Cl. H01L 21/311; H01L 21/02

(52) U.S. Cl. CPC H10P 50/282; H10P 70/23

(57) ABSTRACT

Embodiments described herein relate to a method that includes mapping a distortion of a substrate that includes a device layer over a front side surface of the substrate and a dielectric layer over a backside surface of the substrate. In an embodiment, the method further includes ablating a portion of the dielectric layer with a laser to form an opening in the dielectric layer, where the distortion of the substrate is reduced by forming the opening.

### BACKGROUND

### 1) Field

Embodiments relate to the field of semiconductor manufacturing and, in particular, to systems and methods for improving substrate warpage through localized laser ablation of a backside dielectric layer.

### 2) Description of Related Art

In some semiconductor manufacturing process flows, multiple thin film deposition and patterning cycles are implemented on a substrate, such as a silicon wafer or a silicon carbide substrate, to build functional devices. In many instances, the inclusion of multiple layers may result in the introduction of stresses in the substrate (e.g., thermal stresses, mechanical stresses, and/or the like). The stress induced into the substrate may result in significant substrate distortion (which may sometimes be referred to as substrate saddling or substrate warpage). Highly distorted substrates may result in chucking failure, since the chuck (e.g., an electrostatic chuck (ESC)) may not be able to apply a sufficient chucking force to keep the substrate flat during subsequent deposition and/or patterning processes.

### SUMMARY

Embodiments described herein relate to a method that includes mapping a distortion of a substrate that includes a device layer over a front side surface of the substrate and a dielectric layer over a backside surface of the substrate. In an embodiment, the method further includes ablating a portion of the dielectric layer with a laser to form an opening in the dielectric layer, where the distortion of the substrate is reduced by forming the opening.

Embodiments described herein relate to a method that includes mapping a distortion of a substrate that includes a device layer over a front side surface of the substrate and a dielectric layer over a backside surface of the substrate, and applying a tape over the dielectric layer. In an embodiment, the method may further include ablating a portion of the dielectric layer with a laser to form an opening in the dielectric layer, where the opening reduces a distortion of the substrate. In an embodiment, the method may further include removing the tape from the dielectric layer.

Embodiments described herein relate to a method that includes forming a dielectric layer over a backside surface of a substrate, where the backside surface is opposite from a device layer on the substrate, and mapping a first distortion of the substrate. In an embodiment, the method may further include ablating a portion of the dielectric layer with a laser, where the ablation reduces the first distortion of the substrate to provide a substrate with a second distortion that is less than the first distortion. In an embodiment, the method may further include securing the substrate to a chuck.

### BRIEF DESCRIPTION OF THE DRAWINGS

FIG. 1A is a cross-sectional illustration of a warped substrate with a device layer over a surface of the substrate, in accordance with an embodiment.

FIG. 1B is a cross-sectional illustration of a warped substrate that is being secured to a chuck, in accordance with an embodiment.

FIG. 2A is a cross-sectional illustration of a warped substrate with a device layer and a warpage reduction layer on a backside of the substrate, in accordance with an embodiment.

FIG. 2B is a plan view illustration of the backside of the warped substrate that shows the warpage reduction layer, in accordance with an embodiment.

FIG. 2C is a cross-sectional illustration of the substrate after the warpage reduction layer is selectively patterned with a laser ablation process to form openings in the warpage reduction layer to reduce the warpage of the substrate, in accordance with an embodiment.

FIG. 2D is a plan view illustration of the substrate that illustrates the openings in the warpage reduction layer, in accordance with an embodiment.

FIG. 3A is a cross-sectional illustration of a substrate with a device layer and a warpage reduction layer that is patterned with a laser ablation process, in accordance with an embodiment.

FIG. 3B is a cross-sectional illustration of a substrate with a device layer on one surface and a sacrificial layer and a warpage reduction layer on an opposing surface, in accordance with an embodiment.

FIGS. 4A-4C are cross-sectional illustrations that depict a process for patterning a warpage reduction layer with a laser ablation process, in accordance with an embodiment.

FIGS. 5A-5C are cross-sectional illustrations that depict a process for patterning a warpage reduction layer with a laser ablation process in combination with a tape that is used to contain particulates, in accordance with an embodiment.

FIG. 6 is a schematic illustration of a laser writing system that may be used in order to selectively modify portions of the warpage reduction layer in order to provide a desired amount of warpage control, in accordance with an embodiment.

FIG. 7A is a cross-sectional illustration of a substrate with a first amount of warpage, in accordance with an embodiment.

FIG. 7B is a cross-sectional illustration of the substrate with a second amount of warpage, where the warpage is improved as a result of a laser ablation patterning of a warpage reduction layer on the substrate, in accordance with an embodiment.

FIG. 8 is a flow diagram that depicts a process for reducing the warpage of a substrate through a warpage reduction layer that is selectively patterned with a laser ablation process, in accordance with an embodiment.

FIG. 9 is a flow diagram that depicts a process for reducing the warpage of a substrate through a warpage reduction layer that includes a tape that contains particles generated through a selective laser ablation process, in accordance with an embodiment.

FIG. 10 illustrates a block diagram of an exemplary computer system that may be used in conjunction with a processing tool, in accordance with an embodiment.

### DETAILED DESCRIPTION

Embodiments described herein include systems and methods for improving substrate warpage through localized laser ablation of a backside dielectric layer. In the following description numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

The embodiments illustrated and discussed in relation to the figures included herein are provided for the purpose of explaining some of the basic principles of the disclosure. However, the scope of this disclosure covers all related, potential, and/or possible, embodiments, even those differing from the idealized and/or illustrative examples presented. This disclosure covers even those embodiments which incorporate and/or utilize modern, future, and/or as of the time of this writing unknown, components, devices, systems, etc., as replacements for the functionally equivalent, analogous, and/or similar, components, devices, systems, etc., used in the embodiments illustrated and/or discussed herein for the purpose of explanation, illustration, and example.

As noted above, thermal and/or mechanical stresses that are induced in semiconductor substrates as a result of multi-layer deposition and/or patterning processes may result in significant substrate distortion. High levels of distortion or other warpage may lead to chucking failures since the chuck may not be able to apply a high enough chucking force to flatten the substrate during subsequent deposition and/or patterning processes.

Many efforts have been made to resolve the substrate distortion that can lead to chucking failures. One option is to design more advanced electrostatic chucks (ESC). However, this demands a large financial investment in order to design and implement such designs. An alternative approach is to reduce the substrate distortion to a level that is capable of being chucked by existing ESCs. In some instances, the distortion reduction may be obtained through the deposition of a dielectric layer (e.g., Si₃N₄) of a certain thickness on a backside of the substrate in order to provide an opposing distortion force that results in a net reduction of the substrate distortion.

However, blanket distortion mitigation layers may not be suitable for all applications. For example, substrate distortion may result in the formation of complex substrate geometries. As such, a blanket dielectric coating on the backside surface is not able to address local substrate distortion, which may be needed in some embodiments.

Accordingly, embodiments disclosed herein include a process for forming a dielectric distortion mitigation layer on a backside surface of the substrate. After the distortion mitigation layer is formed, selected regions of the dielectric distortion mitigation layer may be patterned (e.g., through a laser ablation process and/or a laser induced lift-off process) in order to locally modify the distortion of the substrate in order to address local substrate distortion. For example, a map of the distortion (e.g., an out-of-plane distortion (OPD) map) of the substrate may be formed with any suitable metrology process, such as ellipsometry, profilometry, or the like. The map of the distortion can be used to determine which areas of the dielectric distortion mitigation layer need to be ablated in order to reduce the distortion of the substrate.

Selectively patterning the dielectric distortion mitigation layer allows for localized changes to the stress response of the dielectric layer. That is, the stress induced in the underlying substrate by the dielectric layer can be controlled across the surface of the substrate. This allows for high warpage (or high distortion) areas to be specifically targeted for warpage reduction. Therefore, the selective treatment can be used to locally modify the distortion of the substrate in order to reduce the warpage to a level that can be secured with existing chucks in a processing chamber.

In some embodiments, the patterning process may include a laser induced lift-off process. In such an embodiment, the laser is focused at an interface between the substrate and the overlying dielectric layer. The laser may be chosen so that the laser beam substantially passes through the dielectric layer and induces heating of the surface of the substrate. This can result in the formation of plasma and/or vapor pressure that drives ablation and/or lift-off of the dielectric layer. In some embodiments, the wavelength of the laser may be chosen so that the dielectric layer is substantially transparent to the laser. A desired level of laser absorption in the dielectric layer may be provided through choice of material of the dielectric layer and/or selection of the wavelength of the laser. For example, the dielectric layer may comprise silicon and nitrogen with a stoichiometric ratio of silicon and nitrogen or a non-stoichiometric ratio of silicon and nitrogen. In another embodiment, the patterning process may include a direct laser ablation of the dielectric layer. In such an embodiment, the dielectric layer may be tuned to absorb the laser irradiation so that the dielectric layer is directly ablated by the laser.

In yet another embodiment, the substrate may be further protected from the laser by providing a sacrificial layer between the dielectric layer and the substrate. For example, the sacrificial layer may comprise a material that is tuned to be substantially opaque to the laser. In some instances, the sacrificial layer may comprise an amorphous carbon material or the like.

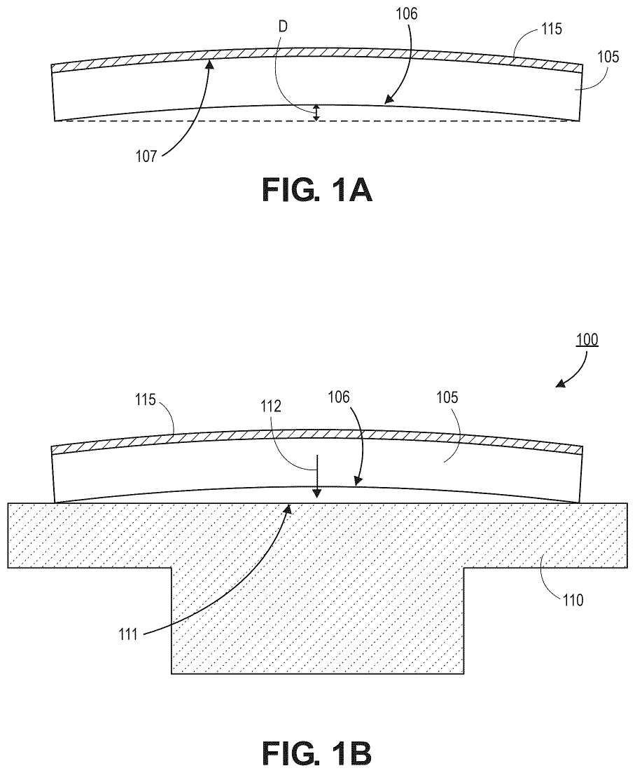

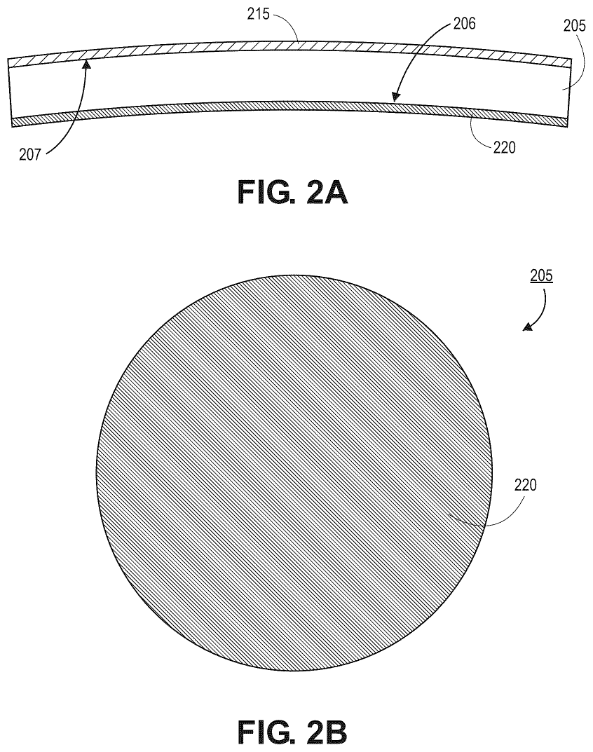

Referring now to FIG. 1A, a cross-sectional illustration of a substrate 105 is shown, in accordance with an embodiment. In an embodiment, the substrate 105 may be any type of substrate used in semiconductor manufacturing. For example, the substrate may be a silicon (Si) wafer, a silicon carbide (SIC) wafer, or the like. The substrate 105 may have any form factor, such as form factors common in semiconductor manufacturing (e.g., a 300 mm diameter wafer or any other common diameter wafer).

The substrate 105 may have a front surface 107 and a backside surface 106 that is opposite from the front surface 107. In an embodiment, a device layer 115 is formed over the front surface 107 of the substrate 105. The device layer 115 may comprise one or more layers that are provided in a stack in order to form a functional device on the substrate 105. For example, a plurality of layers that comprises the same material composition or different material compositions may be formed as part of the device layer 115. In an embodiment, one or more of the layers of the device layer 115 may be patterned (e.g., with an etching process or the like).

As noted above, the formation of a device layer 115 on the front surface 107 of the substrate 105 may result in the formation of distortion in the substrate 105. For example, thermal induced stresses (e.g., due to coefficient of thermal expansion (CTE) mismatch between the device layer 115 and the substrate 105) may result in warpage of the substrate 105. In the particular embodiment shown in FIG. 1A, the warpage is illustrated as a convex bowing of the front surface 107. The backside surface 106 may have a corresponding bow. For example, a distance between an apex of the backside surface 106 and a bottom of an outer edge of the substrate 105 along the backside surface 106 may have a distance D. The distance D may be approximately 300 μm or higher in some instances.

Referring now to FIG. 1B, a cross-sectional illustration of a portion of a processing tool 100 is shown, in accordance with an embodiment. In an embodiment, the processing tool 100 may comprise a chuck 110 that is within a chamber (not shown). The chuck 110 may be an any suitable chuck, such as an ESC, a vacuum chuck, or the like. The chuck 110 may generate a chucking force 112 (as indicated by the arrow) that secures the substrate 105 to a surface 111 of the chuck 110 in order to provide a substantially flat surface onto which additional layers may be deposited on the device layer 115 or so that patterning (e.g., etching, etc.) may be implemented on existing layers of the device layer 115.

As can be appreciated the ability to form a flat surface is important for providing good process uniformity. However, when the distortion is above a certain amount (e.g., above approximately 300 μm), the chucking force 112 may not be able to provide the desired flatness to the substrate 105. Alternatively, the chucking force 112 may be too high, which may cause damage to the substrate 105 and/or the device layer 115. That is, the chuck 110 may only be compatible with a given maximum distortion.

Accordingly, embodiments disclosed herein may include a process that includes forming a dielectric layer on the backside surface 106 of the substrate 105, and the dielectric layer may be selectively patterned in order to accommodate complex distortion profiles of the substrate 105. For example, the dielectric layer may be ablated by a laser to remove portions of the dielectric layer deposited on the backside surface of the substrate 105 to precisely and selectively adjust and/or correct substrate distortion.

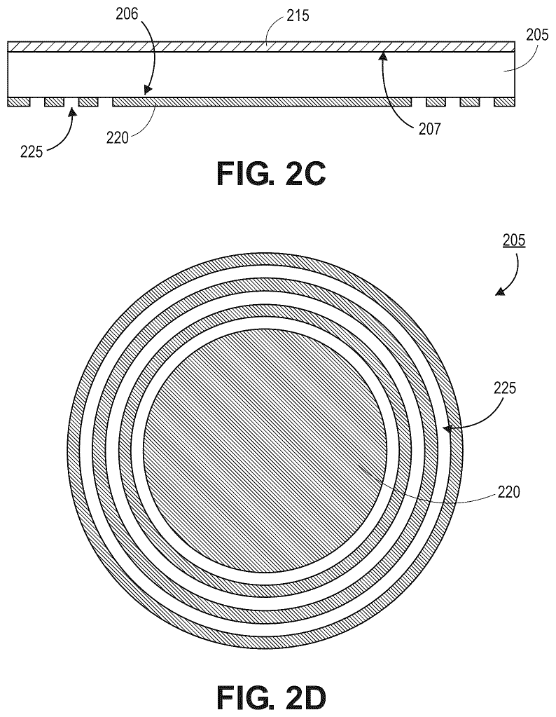

Referring now to FIG. 2A, a cross-sectional illustration of a substrate 205 is shown, in accordance with an embodiment. In an embodiment, the substrate 205 may comprise a front side surface 207 and a backside surface 206. In an embodiment, the substrate 205 may have a degree of distortion, as indicated by the curved front side surface 207 and the curved backside surface 206. While a single curve is shown in FIG. 2A, it is to be appreciated that the distortion of the substrate 205 may include any complex surface profile, such as a saddle, a bowl, a dome, an irregular warpage pattern, and/or the like.

In an embodiment, the substrate 205 may be similar to the substrate 105 described in greater detail above. For example, the substrate 205 may comprise a silicon substrate, a silicon carbide substrate, or the like. The substrate 205 may have a wafer form factor in some embodiments. In an embodiment, a device layer 215 may be formed over the front side surface 207 of the substrate 205. The device layer 215 may comprise one or more layers. One or more of the layers of the device layer 215 may be patterned. In an embodiment, the device layer 215 may be similar to the device layer 115 described in greater detail above.

In an embodiment, a dielectric layer 220 may be formed over the backside surface 206 of the substrate 205. In an embodiment, the dielectric layer 220 may sometimes be referred to as a warpage reduction layer, a distortion reduction layer, or the like. While shown as a single monolithic layer, some embodiments may comprise a dielectric layer 220 that includes a plurality of layers with different material compositions. In a particular embodiment, the dielectric layer 220 may comprise silicon and nitrogen. A silicon nitride based dielectric layer 220 may be beneficial due to the capability of a silicon nitride layer to induce high amplitude stress into the substrate 205. In an embodiment, the dielectric layer 220 may have any suitable thickness. For example, a thickness of the dielectric layer may be between approximately 1.0 μm and approximately 10.0 μm. Though, thinner or thicker dielectric layers 220 may also be used in some embodiments.

In an embodiment, the dielectric layer 220 may comprise a stoichiometric ratio of elements. For example, in the case of a silicon nitride dielectric layer 220, the silicon nitride may have the form SiNx where X is equal to approximately 1.33 (e.g., Si₃N₄). However, non-stoichiometric ratios of the elements may also be used. For example, in a silicon nitride dielectric layer 220 of the form SiNx, X may be less than 1.33. Reducing the concentration of nitrogen in the dielectric layer 220 may reduce the modulus of the dielectric layer 220. However, altering the ratio of silicon to nitrogen may change a bandgap of the dielectric layer 220, which may be beneficial for tuning the selective patterning process of the dielectric layer 220.

Altering the bandgap of the dielectric layer 220 may enable the use of longer wavelength (lower photon energy) lasers for the treatment process. For example, Si₃N₄ may have a bandgap of approximately 4.6 eV, whereas SiN has a bandgap of approximately 2.25 eV, and SiN_{0.67} has a bandgap of approximately 1.7 eV. As such, the longer wavelength lasers will still substantially absorb within the dielectric layer 220 instead of potentially damaging the underlying substrate 205 (e.g., with unwanted ablation and/or thermal damage). For example, silicon has a bandgap energy of approximately 1.12 eV, and 4H: SiC has a bandgap of approximately 3.25 eV. In this way a single dielectric layer 220 may be used without the need of an additional sacrificial layer to protect the substrate 205 from damage. Though, as will be described in greater detail herein, a sacrificial layer may also be used in some embodiments.

Referring now to FIG. 2B, a plan view illustration of the dielectric layer 220 on the backside surface 206 of the substrate 205 is shown, in accordance with an embodiment. As shown, the dielectric layer 220 may be a substantially uniform layer (e.g., a blanket layer) that is provided over the backside surface 206 of the substrate 205. In an embodiment, the dielectric layer 220 may be deposited on the substrate 205 with any suitable deposition process, such as a chemical vapor deposition (CVD) process, or the like.

Referring now to FIG. 2C, a cross-sectional illustration of the substrate 205 after the dielectric layer 220 is selectively patterned is shown, in accordance with an embodiment. As shown, the patterning of the dielectric layer 220 may reduce the distortion of the substrate 205. In the illustrated embodiment, the distortion is substantially removed (e.g., the front side surface 207 and the backside surface 206 are substantially flat). Though, in other embodiments, the distortion reduction may reduce the distortion by an amount that allows the substrate 205 to be chucked by a chuck (such as chuck 110 described in greater detail above). For example, the distortion of the substrate 205 may be reduced to less than approximately 300 μm in some embodiments.

In an embodiment, the dielectric layer 220 may be patterned with a laser in order to produced openings 225 of the dielectric layer 220. In an embodiment, the selection of the location of the openings 225 in the dielectric layer may be made after mapping the distortion of the substrate 205. The distortion may be mapped in order to provide an out of plane distortion (OPD) map. The substrate 205 may be mapped with any suitable metrology process, such as ellipsometry, profilometry, or the like.

Once the distortion is mapped, portions of the dielectric layer 220 that need to be removed are determined. For example, the modification implemented by laser ablation may result in the removal of portions of the dielectric layer 220 to form the openings 225. The portions of the dielectric layer 220 may be removed through a lift-off process and/or through direct laser ablation. The change in modulus that is provided by forming the openings 225 alters the amount of stress that is locally induced into the substrate 205 in order to provide a desired amount of warpage mitigation proximate to the openings 225.

In an embodiment, the laser is focused at an interface between the substrate 205 and the overlying dielectric layer 220. The laser may be chosen so that the laser beam substantially passes through the dielectric layer 220 and induces heating of the surface of the substrate 205. This can result in the formation of plasma and/or vapor pressure that drives ablation and/or lift-off of the dielectric layer 220. In some embodiments, the wavelength of the laser may be chosen so that the dielectric layer 220 is substantially transparent to the laser. In another embodiment, the patterning process may include a direct laser ablation of the dielectric layer 220. In such an embodiment, the dielectric layer 220 may be tuned to absorb the laser irradiation so that the dielectric layer 220 is directly ablated by the laser.

In an embodiment, the openings 225 of the dielectric layer 220 may be provided proximate to locations of the substrate 205 that have undergone more severe distortion than other regions of the substrate 205. In the example shown in FIG. 2C and the plan view illustration in FIG. 2D, the openings 225 are circular rings proximate to an edge of the substrate 205. However, it is to be appreciated that the openings 225 may comprise rings of any shape, lines of any shape, solid shapes (e.g., polygons, circles elliptical shapes, or the like). Further, while the openings 225 are shown as passing through an entire thickness of the dielectric layer 220, embodiments may include openings 225 that partially pass through a thickness of the dielectric layer 220.

In some embodiments, the laser patterning process may result in the formation of particles (not shown). The particles may be removed with a wet cleaning process in some embodiments. However, when a wet cleaning process is not preferable or allowed by design rules, embodiments may include the use of a dicing tape over the dielectric layer in order to retain particles during the patterning process. The use of a dicing tape embodiment will be described in greater detail herein.

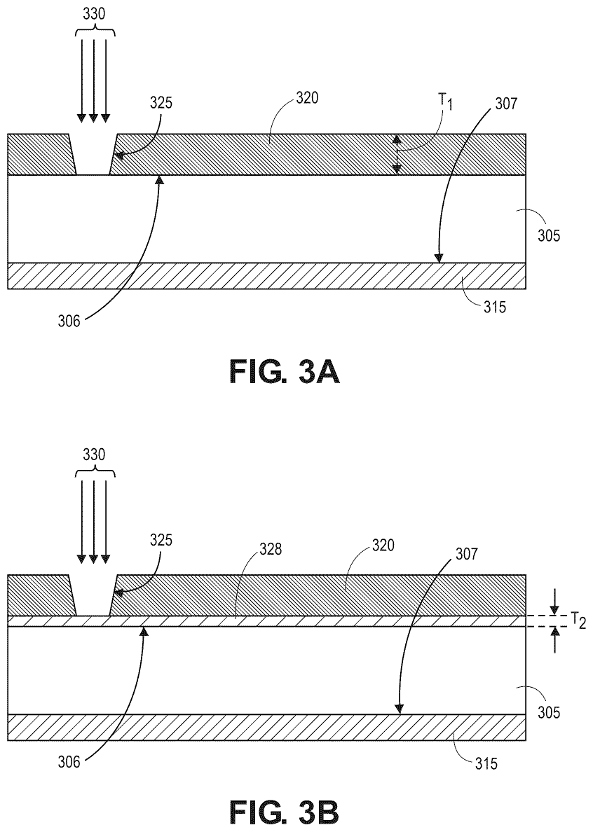

Referring now to FIG. 3A, a cross-sectional illustration of a substrate 305 that illustrates the result of a laser ablation process on the dielectric layer 320 is shown, in accordance with an embodiment. In an embodiment, the substrate 305 may be similar to any of the substrates described in greater detail herein. For example, the substrate 305 may be a silicon wafer or a silicon carbide wafer. The substrate 305 may comprise a front side surface 307 with a device layer 315 formed over the front side surface 307, and a backside surface 306 with the dielectric layer 320 formed over the backside surface 306. The device layer 315 may be similar to any of the device layers described herein, and the dielectric layer 320 may be similar to any of the dielectric layers described herein. For example, the dielectric layer 320 may comprise silicon and nitrogen with any suitable ratio between silicon and nitrogen, and the dielectric layer 320 may have a thickness Ti that is between approximately 1 μm and approximately 10 μm.

As shown in FIG. 3A, the dielectric layer 320 may be exposed to laser irradiation 330. The laser irradiation 330 may result in the lift-off and/or ablation of portions of the dielectric layer 320 in order to form an opening 325 in the dielectric layer 320. In the illustrated embodiment, the opening 325 may have sloped sidewalls that are typical of laser ablation processes. In some embodiments, the laser beam is passed through a mask or a diffractive optical element (DOE) module that is adopted to project or pattern the laser irradiation 330 with a certain width and length or other shapes onto the dielectric layer 320 to ablate the desired portion of the dielectric layer 320 in order to form the opening 325.

In an embodiment, the type of laser chosen to treat the dielectric layer 320 may be based on the bandgap of the dielectric layer 320. For example, when the laser beam is focused at the interface of the dielectric layer 320 and the substrate 305, the wavelength of the laser may be selected to be highly transparent to the dielectric layer 320, but highly absorbing to the substrate 305. For example, silicon has a bandgap energy of 1.12 eV, and 4H: SiC has bandgap that is 3.25 eV. In the case of a silicon nitride (Si₃N₄) dielectric layer 320, the bandgap of the dielectric layer 320 is 4.6 eV. As such, lasers with a wavelength larger than approximately 340 nm (3.5 eV) are mostly transparent to the dielectric layer. The heating of the surface of the substrate 305 induces plasma or vapor pressure to ablation and lift off the irradiated portions of the dielectric layer 320 with minimum damage to the underlying substrate 305.

In some embodiments, the laser irradiation 330 may include a short pulse UV laser, such as a picosecond or femtosecond 355 nm UV laser. Other lasers, such as a femtosecond green (532 nm) laser, have also been shown as being capable of providing the desired patterning in the dielectric layer 320.

Depending on the specific dielectric film material, longer wavelength, less expensive solid-state lasers such as a 1064 nm infrared (1.15 eV) laser may be also used. Such a laser may be particularly beneficial with the adoption of a sacrificing barrier layer (described in greater detail below) to further reduce damage of wafer substrate. In some embodiments, a heat affected zone (HAZ) of the substrate 305 may be minimized by using short pulses of the laser irradiation. For example, a pulse width that is less than 5 ns or less than 15 ps may be used.

When improved protection of the substrate 305 is desired, a sacrificial barrier layer may also be formed between the dielectric layer 320 and the substrate 305. An example of such an embodiment is shown in FIG. 3B. The substrate in FIG. 3B may be substantially similar to the substrate 305 in FIG. 3A, with the exception of the addition of a sacrificial barrier layer 328 between the dielectric layer 320 and the backside surface 306 of the substrate 305. In an embodiment, the sacrificial barrier layer 328 may have a thickness T2 that is less than a thickness Ti of the substrate 305. Depending on the material of the sacrificial barrier layer 328, the thickness T2 may be approximately 1.0 μm or less. For example, the thickness T2 may be tens of nanometers or less.

In an embodiment, the sacrificial barrier layer 328 may be a material with a bandgap that is lower than the bandgap of the dielectric layer 320 and/or lower than the bandgap of the substrate 305 may be used. In a particular embodiment, the sacrificial barrier layer 328 may have a bandgap that is less than approximately 1.0 eV. In one embodiment, the sacrificial barrier layer 328 may comprise an amorphous carbon material. Some amorphous carbon materials may have a bandgap that is approximately 0.3 eV or lower. Due to the small bandgap, the laser irradiation 330 is substantially absorbed (by a combination of the dielectric layer 320 and the sacrificial barrier layer 328) before reaching the substrate 305. Accordingly, damage to the substrate 305 due to laser irradiation 330 is substantially eliminated.

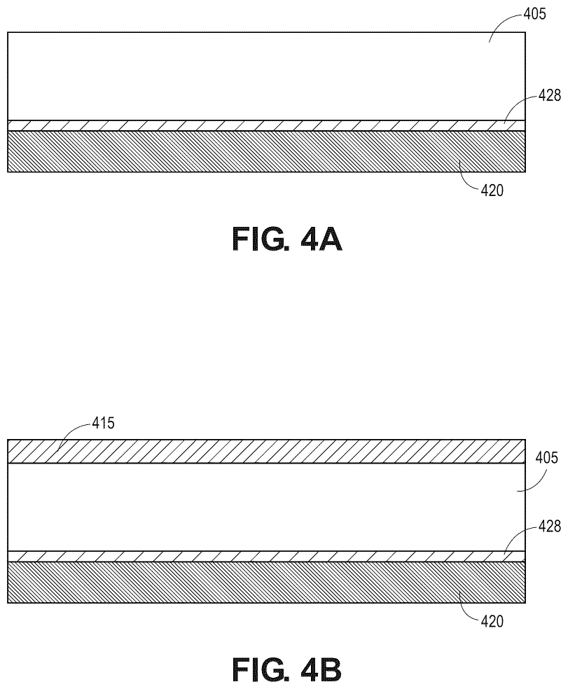

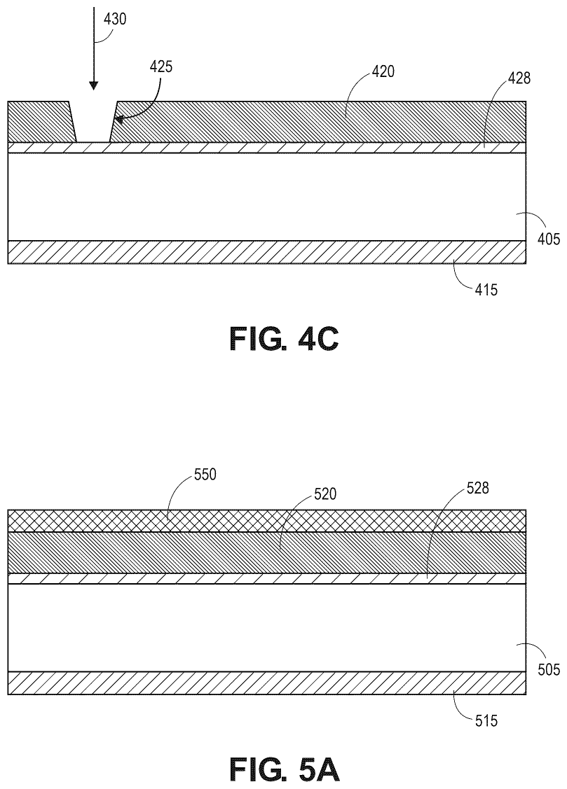

Referring now to FIGS. 4A-4C , a series of cross-sectional illustrations that depict a process for patterning a dielectric layer for warpage reduction purposes is shown, in accordance with an embodiment.

Referring now to FIG. 4A, a cross-sectional illustration of a substrate 405 is shown, in accordance with an embodiment. In an embodiment, the substrate 405 may be similar to any of the substrates described in greater detail herein. For example, the substrate may comprise a silicon wafer or a silicon carbide wafer. A dielectric layer 420 may be provided over a surface of the substrate 405. The dielectric layer 420 may be a warpage reduction layer similar to any of the dielectric layers described in greater detail herein. For example, the dielectric layer 420 may comprise silicon nitride. As shown, a sacrificial barrier layer 428 may be provided between the dielectric layer 420 and the substrate 405. The sacrificial barrier layer 428 may comprise amorphous carbon or the like. The sacrificial barrier layer 428 may be similar to any of the sacrificial and/or barrier layers described in greater detail herein.

Referring now to FIG. 4B, a cross-sectional illustration of the substrate 405 after a device layer 415 is formed on a surface of the substrate 405 opposite from the dielectric layer 420. In an embodiment, the device layer 415 may be similar to any of the device layers described in greater detail herein. For example, the device layer 415 may comprise any number of sub-layers, and the sub-layers may have any desired patterning in order to form devices on the substrate 405. While the device layer 415 is shown as being formed after the dielectric layer 420 in FIGS. 4A and 4B, embodiments may include forming the dielectric layer 420 after at least a portion of the device layer 415 is formed.

Referring now to FIG. 4C, a cross-sectional illustration of the substrate 405 after an opening 425 is formed through the dielectric layer 420 is shown, in accordance with an embodiment. In an embodiment, the dielectric layer 420 may be patterned with laser irradiation 430 (e.g., through lift-off and/or laser ablation). The laser patterning process may be similar to any of the laser processes described in greater detail herein. In an embodiment, the position of the opening 425 once the device layer 415 is formed and a map of the distortion of the substrate 405 is generated. In an embodiment, the position of the opening 425 may be chosen to reduce distortion in highly distorted regions.

The patterning of the dielectric layer 420 may result in the formation of particles. In some embodiments, the particles may be cleaned with a wet cleaning process. Wet cleaning is an acceptable cleaning solution for some semiconductor devices. For example, devices formed on silicon carbide wafers may be compatible with wet cleaning operations. However, design rules may prevent wet cleaning for other types of substrates, such as silicon wafers.

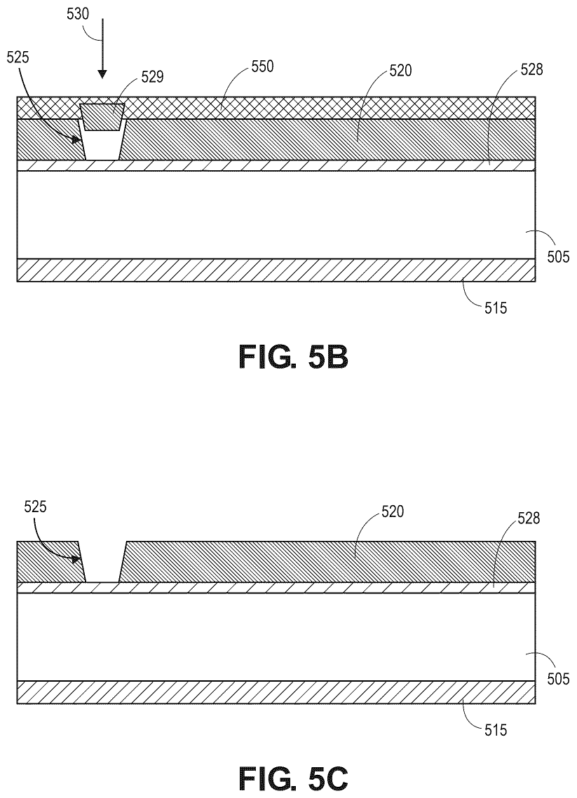

Accordingly, embodiments disclosed herein may also include the use of a dicing tape over the dielectric layer. The dicing tape may capture any particles that are generated. After the patterning, the dicing tape can be removed along with the particles. In such an embodiment, a dry cleaning process (e.g., a plasma clean) may then be used to provide a desired level of cleanliness on the device. An example of such a process is shown in FIGS. 5A-5C.

Referring now to FIG. 5A, a cross-sectional illustration of a substrate 505 is shown, in accordance with an embodiment. In an embodiment, the substrate 505 may be similar to any of the substrates described in greater detail herein. For example, the substrate may comprise a silicon wafer or a silicon carbide wafer. A dielectric layer 520 may be provided over a surface of the substrate 505. The dielectric layer 520 may be a warpage reduction layer similar to any of the dielectric layers described in greater detail herein. For example, the dielectric layer 520 may comprise silicon nitride. As shown, a sacrificial barrier layer 528 may be provided between the dielectric layer 520 and the substrate 505. The sacrificial barrier layer 528 may comprise amorphous carbon or the like. The sacrificial barrier layer 528 may be similar to any of the sacrificial and/or barrier layers described in greater detail herein.

In an embodiment, a device layer 515 is formed on a surface of the substrate 505 opposite from the dielectric layer 520. In an embodiment, the device layer 515 may be similar to any of the device layers described in greater detail herein. For example, the device layer 515 may comprise any number of sub-layers, and the sub-layers may have any desired patterning in order to form devices on the substrate 505.

In an embodiment, a tape 550 may be applied over the dielectric layer 520 in order to prevent particles from spreading during patterning of the dielectric layer 520. In an embodiment, the tape 550 may be a dicing tape or the like. For example, the tape 550 may be substantially transparent to the laser used to pattern the dielectric layer 520. While a tape 550 is shown on the dielectric layer 520, embodiments may also include applying a tape 550 on the device layer 515 to provide protection to the device layer 515 from any particles that may escape the tape 550 over the dielectric layer 520.

Referring now to FIG. 5B, a cross-sectional illustration of the substrate 505 during a laser patterning process is shown, in accordance with an embodiment. In an embodiment, the laser irradiation 530 passes through the tape 550. The laser irradiation 530 may result in the lift-off of a particle 529 and/or ablation that may result in the formation of particles 529 proximate to the openings 525 formed in the dielectric layer 520. As shown, the particle 529 is captured by the tape 550 so that the particle 529 is not released to an external environment.

Referring now to FIG. 5C, a cross-sectional illustration of the substrate 505 after the tape 550 is removed is shown, in accordance with an embodiment. In an embodiment, the tape 550 may be cured with an exposure to UV radiation in order to reduce the adhesion of the tape 550. The tape 550 may then be removed from the dielectric layer 520, and the tape 550 may retain any particles 529 that were captured by the tape 550 during the patterning process. In an embodiment, a dry cleaning process (e.g., a plasma clean) may be implemented after the tape 550 is removed.

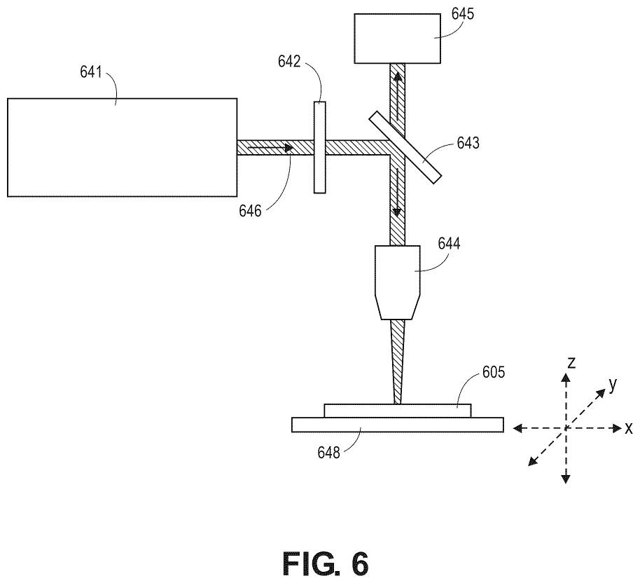

In an embodiment, the laser irradiation may be provided to selected regions of the dielectric layer by moving the substrate relative to a stationary laser, moving the laser (and/or the laser beam) relative to a stationary substrate, or by moving both the substrate and the laser (and/or the laser beam). An example of a stationary laser and laser beam with a displaceable substrate is shown in FIG. 6.

Referring now to FIG. 6, a cross-sectional schematic illustration of a laser irradiation system is shown, in accordance with an embodiment. In an embodiment, the system may comprise a displaceable stage 648 that supports a substrate 605. In an embodiment, the substrate 605 may be similar to any of the substrates described in greater detail herein. For example, the substrate 605 may have a dielectric layer (not shown) that is irradiated in order to modify distortion of the substrate 605. In an embodiment, the stage 648 may be displaceable in one or more directions. For example, the stage 648 may be displaceable in one or more of the the X-direction, the Y-directions, and/or the Z-direction.

In an embodiment, the laser 641 may be similar to any of the lasers described herein. In an embodiment, the laser 641 may emit a laser beam 646 that is propagated through a series of optics that direct the laser beam 646 to the substrate 605. The optics may include a shutter 642, a mirror 643 (e.g., a dichroic mirror), a focusing element 644 (e.g., a microscope or other focusing lens or lenses). In some instances, the mirror 643 may route a portion of the laser beam 646 towards an optical detector 645, such as a charge coupled device (CCD) sensor or other type of camera.

In FIG. 6, a fixed laser beam 646 system is shown. Other embodiments may include different ways to selectively modify the dielectric layer of the substrate 605. For example, a scanning laser beam with a galvo scanner or a polygon scanner (either with a stationary or moving stage) may also be used in order to selectively irradiate different portions of the dielectric layer.

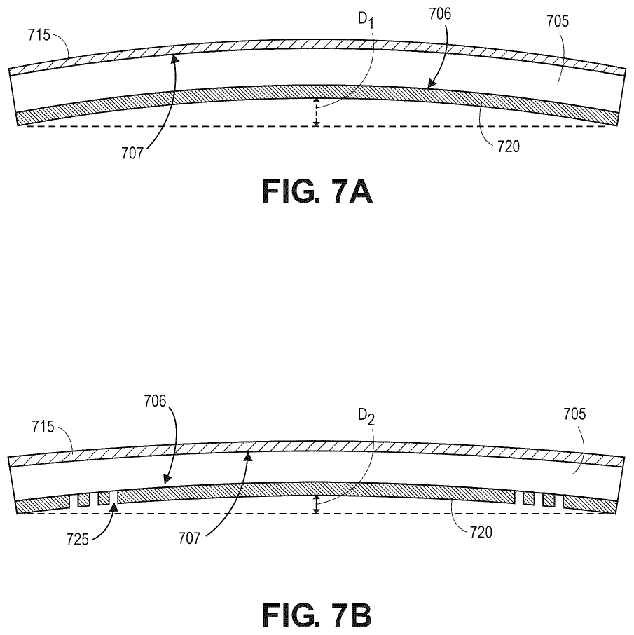

Referring now to FIGS. 7A and 7B, a pair of cross-sectional illustrations of a substrate 705 before and after selective laser patterning of a dielectric layer 720 on the backside surface 706 of the substrate 705 is shown, in accordance with an embodiment. The substrate 705 may be similar to any of the substrates described in greater detail herein. In an embodiment, a device layer 715 may be provided over the front side surface 707 of the substrate 705. As shown, the substrate 705 may have a distortion (as indicated by the distortion Di in FIG. 7A). In an embodiment, the distortion Di may be above the maximum distortion compatible with a given chuck. For example, the distortion D1 may be approximately 300 μm or more.

As shown in FIG. 7B, the dielectric layer 720 has been selectively patterned by a laser to form openings 725. The openings 725 may be formed through laser ablation and/or laser induced lift-off, such as processes described in greater detail above. In an embodiment, the location of the openings 725 may be used to reduce the distortion. For example, the distortion D2 may be less than the distortion DI shown in FIG. 7A. In an embodiment, the distortion D2 may be reduced so that the distortion is compatible with the given chuck. That is, the distortion correction provided by the laser patterning of the dielectric layer may at least reduce the distortion, even if the distortion is not completely removed.

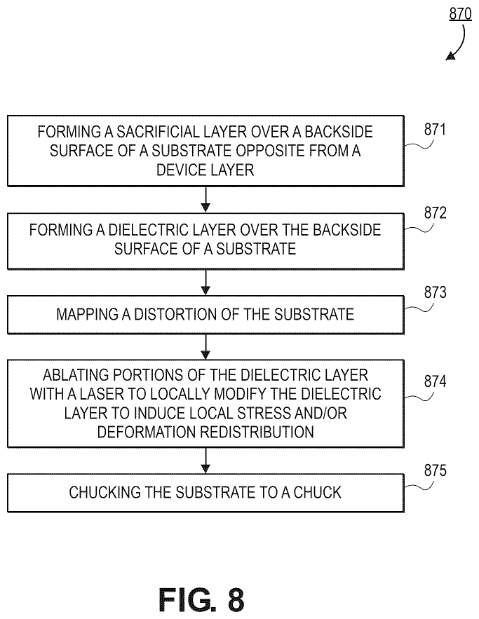

Referring now to FIG. 8, a flow diagram that depicts a process 870 for reducing the distortion of a substrate is shown, in accordance with an embodiment. In an embodiment, the substrate may be a silicon substrate or a silicon carbide substrate. The substrate may be similar to any of the substrates described in greater detail herein. In an embodiment, the process 870 may begin with operation 871, which comprises forming a sacrificial barrier layer over a backside surface of the substrate opposite from a device layer. In an embodiment, the sacrificial barrier layer may comprise a material with a bandgap that is lower than a bandgap of the substrate. For example, the sacrificial barrier layer may comprise an amorphous carbon material. The sacrificial barrier layer may be similar to any of the sacrificial barrier layer materials described in greater detail herein.

In an embodiment, the process 870 may continue with operation 872, which comprises forming a dielectric layer over the backside surface of the substrate. In an embodiment, the dielectric layer may be provided over the sacrificial barrier layer. In embodiments where a sacrificial barrier layer is omitted, the dielectric layer may be formed directly on the backside surface of the substrate. The dielectric layer may comprise silicon and nitrogen or any other suitable dielectric material.

In an embodiment, the process 870 may continue with operation 873, which comprises mapping a distortion of the substrate. In an embodiment, the distortion may be mapped to form an OPD map. In an embodiment, the distortion may be mapped through ellipsometry, profilometry, or the like.

In an embodiment, the process 870 may continue with operation 874, which comprises ablating portions of the dielectric layer with a laser to locally modify the dielectric layer to induce local stress and/or deformation redistribution. In an embodiment, the localized laser ablation (and/or laser induced lift-off) of the dielectric layer may result in the formation of openings in the dielectric layer. In an embodiment, the laser may be similar to any of the lasers described herein.

Additionally, the laser may be pulsed with a pulse duration of 10 ns or smaller, 5 ns or smaller, 20 ps or smaller, or 15 ps or smaller.

After the opening is formed in the dielectric layer, the substrate may be cleaned. In some instances, a wet cleaning process may be used in order to remove particles from the device. For example, a wet cleaning process may be suitable for substrates, such as silicon carbide substrates.

In an embodiment, the process 870 may continue with operation 875, which comprises checking the substrate to a chuck. In an embodiment, the substrate may have the distortion reduced by the selective laser patterning of operation 874. In an embodiment, the distortion of the substrate was reduced so that the chuck is capable of securing the substrate.

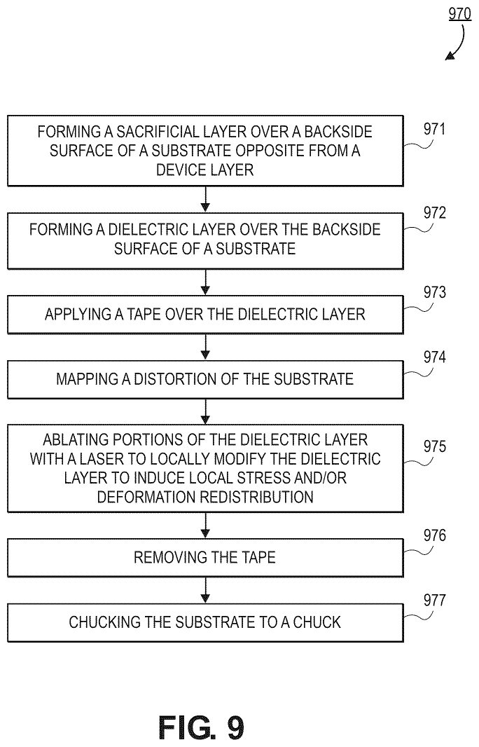

Referring now to FIG. 9, a flow diagram that depicts a process 970 for reducing the distortion of a substrate is shown, in accordance with an embodiment. In an embodiment, the substrate may be a silicon substrate or a silicon carbide substrate. The substrate may be similar to any of the substrates described in greater detail herein. In an embodiment, the process 970 may begin with operation 971, which comprises forming a sacrificial barrier layer over a backside surface of the substrate opposite from a device layer. In an embodiment, the sacrificial barrier layer may comprise a material with a bandgap that is lower than a bandgap of the substrate. For example, the sacrificial barrier layer may comprise an amorphous carbon material. The sacrificial barrier layer may be similar to any of the sacrificial barrier layer materials described in greater detail herein.

In an embodiment, the process 970 may continue with operation 972, which comprises forming a dielectric layer over the backside surface of the substrate. In an embodiment, the dielectric layer may be provided over the sacrificial barrier layer. In embodiments where a sacrificial barrier layer is omitted, the dielectric layer may be formed directly on the backside surface of the substrate. The dielectric layer may comprise silicon and nitrogen or any other suitable dielectric material.

In an embodiment, the process 970 may continue with operation 973, which comprises applying a tape over the dielectric layer. In an embodiment, the tape may comprise a dicing tape or the like. The tape may be a material that is substantially transparent to the laser used to pattern the dielectric layer in a subsequent processing operation.

In an embodiment, the process 970 may continue with operation 974, which comprises mapping a distortion of the substrate. In an embodiment, the distortion may be mapped to form an OPD map. In an embodiment, the distortion may be mapped through ellipsometry, profilometry, or the like.

In an embodiment, the process 970 may continue with operation 975, which comprises ablating portions of the dielectric layer with a laser to locally modify the dielectric layer to induce local stress and/or deformation redistribution. In an embodiment, the localized laser ablation (and/or laser induced lift-off) of the dielectric layer may result in the formation of openings in the dielectric layer. In an embodiment, the laser may be similar to any of the lasers described herein.

Additionally, the laser may be pulsed with a pulse duration of 10 ns or smaller, 5 ns or smaller, 20 ps or smaller, or 15 ps or smaller.

In an embodiment, the process 970 may continue with operation 976, which comprises removing the tape from the dielectric layer. In an embodiment, the tape may capture any of particles that are generated during operation 975.

The tape may then be exposed to UV radiation or the like in order to reduce and adhesive strength of the tape. In an embodiment, the cured tape may be peeled from the dielectric layer while also retaining any particulates from the laser ablation process.

After the opening is the tape is removed, the substrate may be cleaned with a dry cleaning process (e.g., a plasma clean). The use of a dry cleaning process is generally allowable for devices that are fabricated on silicon substrates. As such, processes described herein may be used in combination with silicon wafers, silicon carbide wafers, and/or the like. That is, the use of a tape may provide enhanced flexibility in the use of the processes described herein.

In an embodiment, the process 970 may continue with operation 977, which comprises checking the substrate to a chuck. In an embodiment, the substrate may have the distortion reduced by the selective laser patterning of operation 975. In an embodiment, the distortion of the substrate was reduced so that the chuck is capable of securing the substrate.

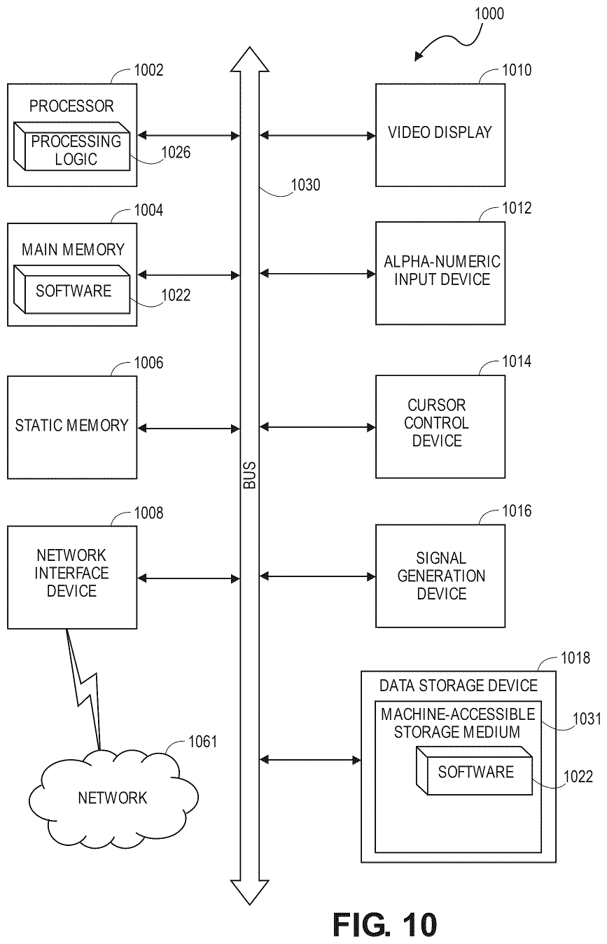

Referring now to FIG. 10, a block diagram of an exemplary computer system 1000 of a processing tool is illustrated in accordance with an embodiment. In an embodiment, computer system 1000 is coupled to and controls processing in the processing tool. Computer system 1000 may be connected (e.g., networked) to other machines in a Local Area Network (LAN), an intranet, an extranet, or the Internet. Computer system 1000 may operate in the capacity of a server or a client machine in a client-server network environment, or as a peer machine in a peer-to-peer (or distributed) network environment. Computer system 1000 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 1000, the term “machine” shall also be taken to include any collection of machines (e.g., computers) that individually or jointly execute a set (or multiple sets) of instructions to perform any one or more of the methodologies described herein.

Computer system 1000 may include a computer program product, or software 1022, having a non-transitory machine-readable medium having stored thereon instructions, which may be used to program computer system 1000 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 1000 includes a system processor 1002, a main memory 1004 (e.g., read-only memory (ROM), flash memory, dynamic random access memory (DRAM) such as synchronous DRAM (SDRAM) or Rambus DRAM (RDRAM), etc.), a static memory 1006 (e.g., flash memory, static random access memory (SRAM), etc.), and a secondary memory 1018 (e.g., a data storage device), which communicate with each other via a bus 1030.

System processor 1002 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 1002 may also be one or more special-purpose processing devices such as an application specific integrated circuit (ASIC), a field programmable gate array (FPGA), a digital signal system processor (DSP), network system processor, or the like. System processor 1002 is configured to execute the processing logic 1026 for performing the operations described herein.

The computer system 1000 may further include a system network interface device 1008 for communicating with other devices or machines. The computer system 1000 may also include a video display unit 1010 (e.g., a liquid crystal display (LCD), a light emitting diode display (LED), or a cathode ray tube (CRT)), an alphanumeric input device 1012 (e.g., a keyboard), a cursor control device 1014 (e.g., a mouse), and a signal generation device 1016 (e.g., a speaker).

The secondary memory 1018 may include a machine-accessible storage medium 1031 (or more specifically a computer-readable storage medium) on which is stored one or more sets of instructions (e.g., software 1022) embodying any one or more of the methodologies or functions described herein. The software 1022 may also reside, completely or at least partially, within the main memory 1004 and/or within the system processor 1002 during execution thereof by the computer system 1000, the main memory 1004 and the system processor 1002 also constituting machine-readable storage media. The software 1022 may further be transmitted or received over a network 1061 via the system network interface device 1008. In an embodiment, the network interface device 1008 may operate using RF coupling, optical coupling, acoustic coupling, or inductive coupling.

While the machine-accessible storage medium 1031 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. A method, comprising:
mapping a distortion of a substrate that comprises a device layer over a front side surface of the substrate and a dielectric layer over a backside surface of the substrate; and
ablating a portion of the dielectric layer with a laser to form an opening in the dielectric layer, wherein the distortion of the substrate is reduced by forming the opening.

2. The method of claim 1, wherein the dielectric layer comprises silicon and nitrogen.

3. The method of claim 2, wherein the dielectric layer comprises silicon and nitrogen with a stoichiometric ratio.

4. The method of claim 2, wherein the dielectric layer comprises silicon and nitrogen with a non-stoichiometric ratio.

5. The method of claim 1, wherein the laser comprises a wavelength that is 340 nm or longer.

6. The method of claim 5, wherein the laser has a pulse duration of 5 ns or shorter.

7. The method of claim 1, wherein a sacrificial barrier layer is provided between the dielectric layer and the substrate, wherein the sacrificial barrier layer has a first bandgap and the substrate has a second bandgap, and wherein the first bandgap is smaller than the second bandgap.

8. The method of claim 7, wherein the sacrificial barrier layer comprises an amorphous carbon layer.

9. The method of claim 1, further comprising:
cleaning the substrate with a wet cleaning process after ablating the portion of the dielectric layer.

10. The method of claim 1, wherein the substrate comprises silicon or wherein the substrate comprises silicon and carbon.

11. A method, comprising:
mapping a distortion of a substrate that comprises a device layer over a front side surface of the substrate and a dielectric layer over a backside surface of the substrate;
applying a tape over the dielectric layer;
ablating a portion of the dielectric layer with a laser to form an opening in the dielectric layer, wherein the opening reduces a distortion of the substrate; and
removing the tape from the dielectric layer.

12. The method of claim 11, further comprising:
cleaning the substrate with a dry cleaning process after the tape is removed from the dielectric layer.

13. The method of claim 11, wherein the tape is transparent to the laser.

14. The method of claim 11, wherein a sacrificial barrier layer is provided between the dielectric layer and the substrate.

15. The method of claim 14, wherein the sacrificial barrier layer comprises a material that is substantially opaque to the laser.

16. The method of claim 11, wherein the dielectric layer comprises silicon and nitrogen.

17. The method of claim 11, wherein the substrate comprises silicon or wherein the substrate comprises silicon and carbon.

18. A method comprising:
forming a dielectric layer over a backside surface of a substrate, wherein the backside surface is opposite from a device layer on the substrate;
mapping a first distortion of the substrate;
ablating a portion of the dielectric layer with a laser, wherein the ablation reduces the first distortion of the substrate to provide a substrate with a second distortion that is less than the first distortion; and
securing the substrate to a chuck.

19. The method of claim 18, wherein the substrate comprises silicon, or wherein the substrate comprises silicon and carbon.

20. The method of claim 18, further comprising:
applying a tape over the dielectric layer before the laser ablation; and
removing the tape after the laser ablation.
